(19) United States
(12) Patent Application Publication
(10) Pub. No.: US 2022/0344457 A1
(43) Pub. Date: Oct. 27, 2022

(54) ENHANCEMENT-MODE HIGH ELECTRON MOBILITY TRANSISTORS WITH SMALL FIN ISOLATION FEATURES

(71) Applicant: NATIONAL RESEARCH COUNCIL OF CANADA, Ottawa (CA)

(72) Inventors: Alireza LOGHMANY, Kanata (CA); Elias AL-ALAM, Ottawa (CA); Jean LAPOINTE, Ottawa (CA)

(21) Appl. No.: 17/761,898

(22) PCT Filed: Sep. 18, 2020
(86) PCT No.: PCT/IB2020/058738

§ 371 Date: Mar. 18, 2022

Related U.S. Application Data
(60) Provisional application No. 62/903,231, filed on Sep. 20, 2019.

(51) Int. Cl. H01L 29/06; H01L 29/66; H01L 29/778; H01L 29/423; H01L 29/40; H01L 21/3065; H01L 21/8252

(52) U.S. Cl. CPC H01L 29/0649; H01L 29/66462; H01L 29/7786; H01L 29/42316; H01L 29/401; H01L 21/3065; H01L 21/8252

(57) ABSTRACT

An enhancement-mode high-electron-mobility transistor (HEMT) having small fin isolation features and methods of fabrication thereof are disclosed. The method of fabrication involves providing semiconductor layers capable of sustaining a two-dimensional electron sheet to enable electrical current to flow through the HEMT, forming a series of trenches and fins in the semiconductor layers over an active area of the semiconductor layers on which a gate contact terminal is to be set down, the fins having widths equal to or less than about 30 nm across, and setting down the gate contact terminal across the fins.

### FIELD

The present specification relates to enhancement-mode high-electron-mobility transistors (HEMTs).

### BACKGROUND

A high-electron-mobility transistor (HEMT) includes a source contact terminal, a drain contact terminal, and a gate contact terminal to which a voltage may be applied to control the flow of electrical current between the source contact terminal and the drain contact terminal. A HEMT may be either a depletion-mode HEMT, which is normally in an “on” state at zero gate-source voltage, or an enhancement-mode HEMT, which is normally in an “off” state at zero gate-source voltage. The use of enhancement-mode HEMTs in circuit design eliminates the need for a negative-polarity voltage supply, and may be preferred in applications in which it is desirable that HEMTs fail in the “off” state.

### SUMMARY

According to an aspect of the specification, a method for fabricating an enhancement-mode high-electron-mobility transistor (HEMT) is provided. The method involves providing semiconductor layers capable of sustaining a two-dimensional electron sheet to enable electrical current to flow through the HEMT. The method further involves forming a series of trenches and fins in the semiconductor layer over an active area of the semiconductor layer on which a gate contact terminal is to be set down, the fins having widths equal to or less than about 30 nm across. The method further involves setting down the gate contact terminal across the fins.

According to another aspect of the specification, a method for fabricating a wafer containing enhancement-mode high-electron-mobility transistors (HEMTs) and depletion-mode HEMTs is provided. The method involves providing semiconductor layers capable of sustaining a two-dimensional electron sheet to enable electrical current to flow through the HEMTs. The method further involves, for each enhancement-mode HEMT, forming a series of trenches and fins in the semiconductor layer over an active area of the semiconductor layer on which a gate contact terminal of the enhancement-mode HEMT is to be set down, the fins having widths equal to or less than about 30 nm across; setting down the gate contact terminal across the fins; and setting down a source contact terminal and a drain contact terminal on either side of the gate contact terminal outside of the active area. The method further involves, for each depletion-mode HEMT, setting down a gate contact terminal, and a source contact terminal and a drain contact terminal on either side of the gate contact terminal.

According to yet another aspect of the specification, a high-electron-mobility transistor (HEMT) is provided. The HEMT includes a drain contact terminal, a source contact terminal, and semiconductor layers. The semiconductor layers are capable of sustaining a two-dimensional electron sheet to enable electrical current to flow through the HEMT. The semiconductor layers include an active area on which a gate contact terminal is to be set down, the active area including a series of trenches and fins, the fins having widths equal to or less than about 30 nm. The HEMT further includes a gate contact terminal set down across the fins.

### BRIEF DESCRIPTION OF THE DRAWINGS

FIG. 1 is a schematic diagram of a cross-section of an example enhancement-mode high-electron-mobility transistor (HEMT) with a gate contact terminal set down over a series of trenches and small fins.

FIG. 2A is a perspective view of the enhancement-mode HEMT of FIG. 1.

FIG. 2B is a close-up perspective view of a portion of the trenches and fins shown in FIG. 2A.

FIG. 3 is a flowchart of an example method to fabricate a gate contact terminal set down over small fin features for an enhancement-mode HEMT.

FIG. 4A a schematic diagram of a first stage of fabrication of an example of a gate contact terminal set down over small fin features, prior to dry etching of the trenches for a HEMT.

FIG. 4B is a schematic diagram of a second stage of fabrication of the active area of FIG. 4A with the fins dry etched into the semiconductor layers.

FIG. 4C is a schematic diagram of a third stage of fabrication of the active area of FIG. 4A with a gate contact terminal set down over the fins.

FIG. 5 is a flowchart of an example method to form trenches in a semiconductor layer of an enhancement-mode HEMT.

FIG. 6 is a flowchart of an example method to fabricate a wafer containing enhancement-mode HEMTs and depletion-mode HEMTs.

### DETAILED DESCRIPTION

High-electron-mobility transistors (HEMTs) may be designed to have a wide bandgap, high breakdown voltage, high peak electron drift velocity, and the high concentration of two-dimensional electron gas. Such characteristics may be provided by the use of semiconductor layers made of aluminum gallium nitride (AlGaN) and gallium nitride (GaN).

However, fabricating a HEMT with such characteristics in enhancement mode may be challenging. Previous attempts employed techniques such as barrier-thinning and fluoride-based plasma treatment, which may result in high gate-leakage current and the possibility of hysteresis in the gate characteristics of such enhancement-mode HEMTs. These drawbacks may be caused by surface damage and ease of tunnelling through a thinned-barrier, in the case of barrier-thinning, and/or by movement of fluorine ions, in the case of fluoride-based plasma treatment. Other techniques involve the reduction of the size of fins, but so far such fin features have only been fabricated at sizes as low as about 50 nanometers. At this size, such fin features result in HEMTs with positive threshold voltages nearly equal to about 0 volts, but this is unsatisfactory for the fabrication of reliable normally-off enhancement-mode HEMTs.

Described herein are methods to fabricate reliably normally-off enhancement-mode HEMT5 that involve the fabrication of fins at sizes equal to or less than about 30 nanometers. Such small fin feature sizes may be realized by the use of electron beam lithography and inductively coupled plasma-reactive ion etching (ICP-RIE). These fins are separated by trenches etched in the active area of the HEMT, the fins having widths less than or equal to about 30 nanometers. The reduced widths of the fins may cause the HEMT to reliably operate in enhancement-mode by the tri-gate concept and/or polarization relaxation.

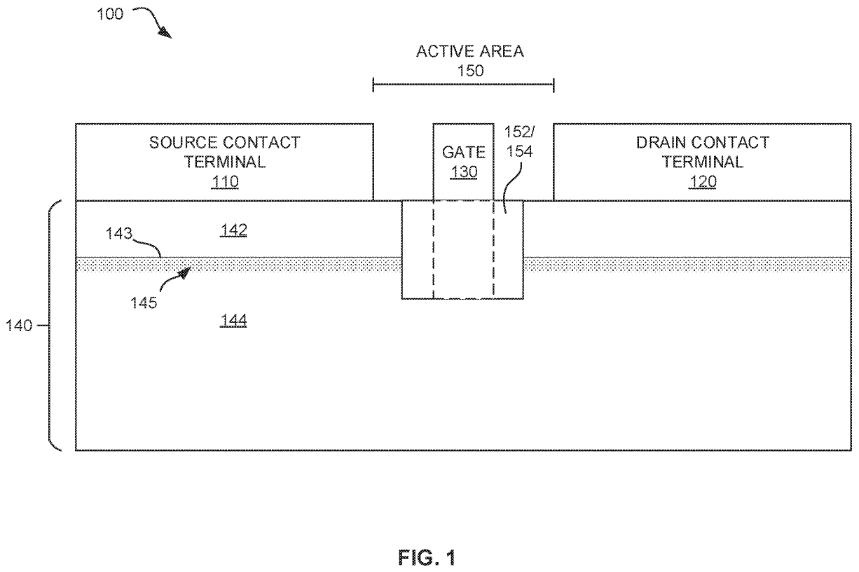

FIG. 1 is a schematic diagram of a cross-section of an example enhancement-mode high-electron-mobility transistor (HEMT) 100. The HEMT 100 includes a source contact terminal 110, a drain contact terminal 120, and a gate contact terminal 130. The source contact terminal 110, drain contact terminal 120, and gate contact terminal 130 are metal conductors. The HEMT 100 is a “normally off” or “enhancement-mode” HEMT, and thus, when a sufficient voltage is applied to the gate contact terminal 130, electrical current flows through the HEMT 100 between the source contact terminal 110 and drain contact terminal 120.

The HEMT 100 further includes semiconductor layers 140 capable of sustaining a two-dimensional electron sheet to enable electrical current to flow through the HEMT 100. The semiconductor layers 140 comprises a first semiconductor layer, or barrier 142, of a first semiconductor material, and a second semiconductor layer, or channel 144, of a second semiconductor material underneath the barrier 142. The barrier 142 and channel 144 form layers that run continuously beneath the source contact terminal 110 and drain contact terminal 120 (the continuous path is not shown in the cross-section of FIG. 1, because it is out of the plane). The gate contact terminal 130 is set down within an active area 150 some of which is corrugated with small fins 154 and trenches 152, as discussed in greater detail below.

The second semiconductor material has a different band gap than the first semiconductor material, and thus a heterointerface 143 is formed between the barrier 142 and the channel 144. The channel 144 includes a region in which a two-dimensional electron sheet is formed, referred to herein as the two-dimensional electron sheet region 145. The two-dimensional electron sheet region 145 is in the channel 144 and adjacent to the heterointerface 143. The thickness of the two-dimensional electron sheet region 145 is exaggerated in the Figures for illustrative purposes, but it is to be understood that the thickness of the two-dimensional electron sheet region 145 may have a thickness of only about 1-2 nanometers. Further, it is to be understood that the channel 144 is an upper portion of a deeper layer of the second semiconductor material, below which may include the substrate wafer and any additional layer(s) epitaxially grown (not shown in FIG. 1) to accommodate lattice mismatch between the substrate wafer and the channel 144.

When a first voltage source is used to apply a voltage greater than a threshold voltage to the gate contact terminal 130, electrons accumulate in a two-dimensional electron sheet region 145 under the gate contact terminal 130 in the fins 154, thereby allowing electrical current to flow between the source contact terminal 110 and drain contact terminal 120, when a second voltage source is used to apply a voltage difference between the source and drain.

The second semiconductor material is selected to serve as a HEMT channel and the first semiconductor material is selected to serve as a HEMT barrier compatible with the channel. In the present example, the first semiconductor material includes aluminum gallium nitride (AlGaN) and the second semiconductor material may include gallium nitride (GaN).

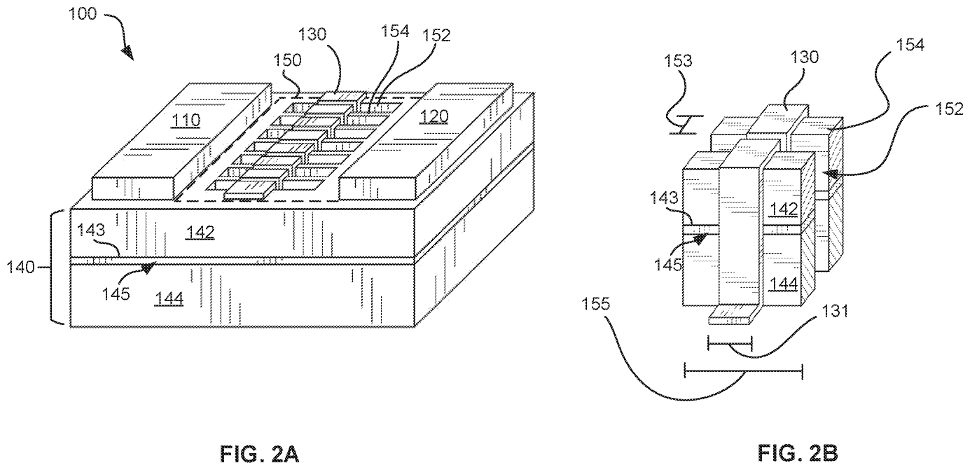

As mentioned above, the semiconductor layers 140 includes the active area 150 on which a gate contact terminal 130 is to be set. The active area 150 includes a series of fins 154 having widths 153 (See FIG. 2B) equal to or less than about 30 nanometers. In other words, the fins 154 span a distance of less than or about 30 nanometers across. The fins 154 are separated by trenches 152 of the etched portions of the semiconductor layer 140 between the fins 154. FIG. 2A and 2B provide perspective views of the HEMT 100 and the trenches 152 and fins 154. The active area 150 spans from an edge of the source contact terminal 110 to an edge of the drain contact terminal 120. The gate contact terminal 130 has a gate width 131. Further, the fins 154 have lengths 155 that can be equal to, less than, or larger than the gate width 131.

The gate contact terminal 130 is set down across the fins 154. The trenches 152 and fins 154 run perpendicular to the direction of the gate contact terminal 130, as shown in FIG. 2A and 2B. The gate contact terminal 130 is situated between the source contact terminal 110 and drain contact terminal 120.

Some segments of the gate contact terminal 130 rest on top of the barrier 142 or on a thin insulator layer (the latter not shown), forming either a Schottky contact or metal-insulator-semiconductor structure. Further, some segments of the gate contact terminal 130 that run down the trenches 152 rest adjacent to the inner side walls of the trenches 152, which may be of the barrier 142 or the channel 144. Further, some segments of the gate contact terminal 130 rest on the bottoms of the trenches 152 in the channel 144.

The trenches 152 extend through the semiconductor layer 140 past a depth at which the two-dimensional electron sheet is to be formed, or in other words, past the two-dimensional electron sheet region 145. Thus, in some examples, the trenches 152 may extend about 40 nanometers into the semiconductor layer 140, depending on the depth of the heterointerface 143.

As mentioned previously, the widths 153 of the fins 154 are equal to or less than about 30 nanometers.

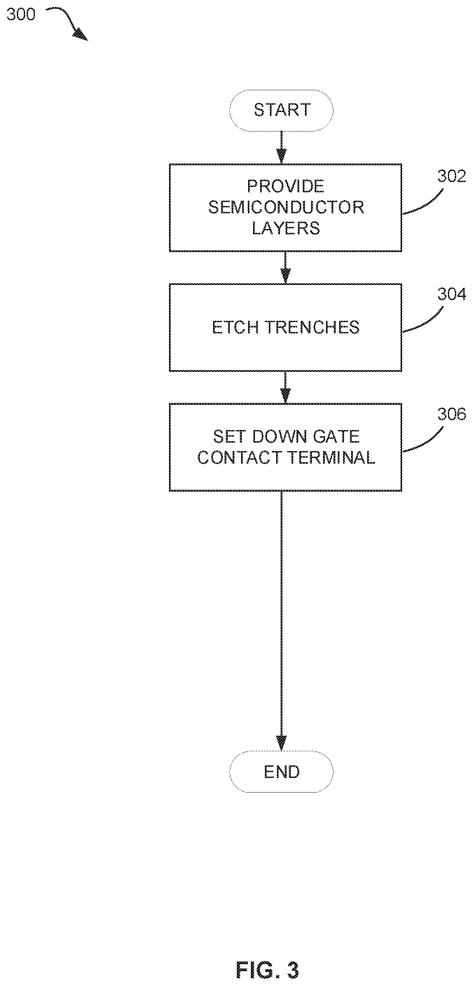

FIG. 3 is a flowchart of an example method 300 to fabricate a gate contact terminal set down over small fins for an enhancement-mode HEMT. Such an enhancement-mode HEW may be similar to the HEMT 100 of FIG. 1.

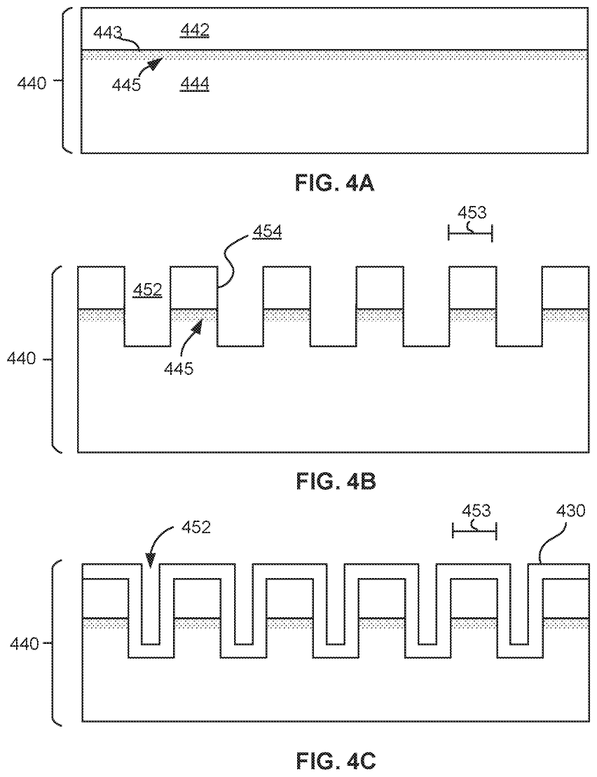

At block 302, semiconductor layers capable of sustaining a two-dimensional electron sheet to enable electrical current to flow through the HEMI are provided. The semiconductor layers may be similar to the semiconductor layers 142 and 144 of semiconductor layers 140 of FIG. 1, and thus for further description of such semiconductor layers, reference to the semiconductor layers 140 of FIG. 1 may be had. An example of semiconductor layers 440 is shown in FIG. 4A, including a barrier 442, channel 444, heterointerface 443, and two-dimensional electron sheet region 445.

Returning to FIG. 3, at block 304, a series of trenches in the semiconductor layer are etched within an active area of the semiconductor layer to create a series of fins on which a gate contact terminal is to be set down. The fins which have widths less than about 30 nm across, and are separated by trenches. Such fins may be similar to the fins 154 of FIG. 2B, and thus for further description of such trenches, reference to the trenches 152 of FIG. 2B may be had.

An example of semiconductor layers 440 with such trenches formed therein is shown in FIG. 4B as trenches 452 spaced apart by fins 454. In FIG. 4B, it can be seen that the trenches 452 extend through the semiconductor 440 layer past a depth at which the two-dimensional electron sheet is to be formed, or in other words, past the two-dimensional electron sheet region 445.

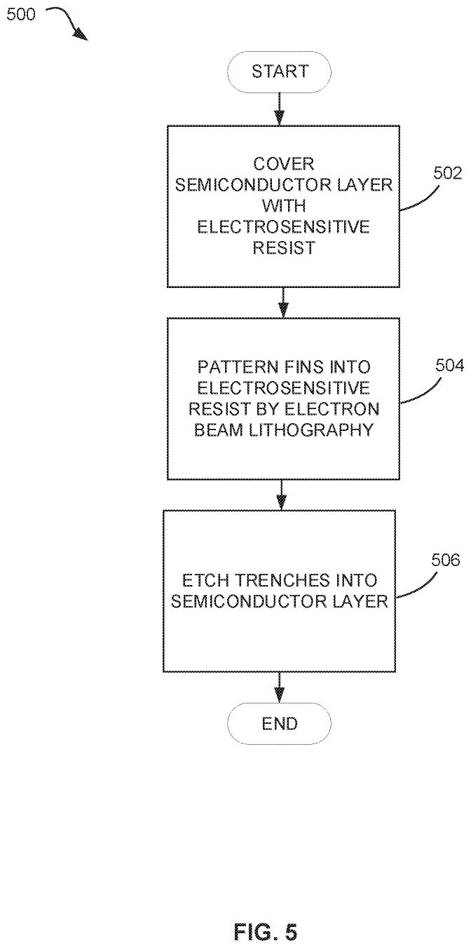

The trenches 452 may be formed in the semiconductor layer 440 by a combination of electron beam lithography and dry etching, as described in greater detail in FIG. 5, below.

Returning to FIG. 3, at block 306, a gate contact terminal is set down across the fins. The gate contact terminal may be similar to the gate contact terminal 130 of FIG. 1, and thus for further description of such a gate contact terminal, reference to the gate contact terminal 130 of FIG. 1 may be had.

An example of semiconductor layers 440 with trenches 452 and fins 454 formed therein and a gate contact terminal 430 set down across the fins 454 is shown in FIG. 4C. In FIG. 4C, it can be seen that the gate contact terminal 430 is set down perpendicular to the trenches 452 and fins 454.

FIG. 5 is a flowchart of an example method 500 to form trenches in semiconductor layers of an enhancement-mode HEMT. Thus, the method 500 may be understood to be one example of how block 304 of the method 300 of FIG. 3 may be performed.

At block 502, the semiconductor layers are covered with an electrosensitive resist layer. The electrosensitive resist layer may include hydrogen silsesquioxane (HSQ).

At block 504, the series of fins are patterned using the electrosensitive resist layer by electron beam lithography, thereby forming a mask from the electrosensitive resist layer. The HSQ that is exposed to the electron beam of a sufficient dose is converted into silicon oxide. The unexposed HSQ can be removed as waste by an intermediate development step. The HSQ is a high-resolution resist, and is particularly well-suited for this application since the exposed resist provides a suitable mask for subsequent plasma etching of the semiconductor layer. A typical polymer resist layer may not withstand the subsequent plasma etching, and alternatively, the use of a sacrificial hard mask may introduce complexity and risk of damaging the semiconductor layers.

At block 506, the series of trenches is dry etched into the semiconductor layer through the mask. The trenches may be dry etched with chlorine-based dry etching and by inductively coupled plasma-reactive ion etching (ICP-RIE). Thus, small isolation features in the form of small fins spaced part by trenches may be fabricated, with the fins having widths equal to or less than about 30 nm.

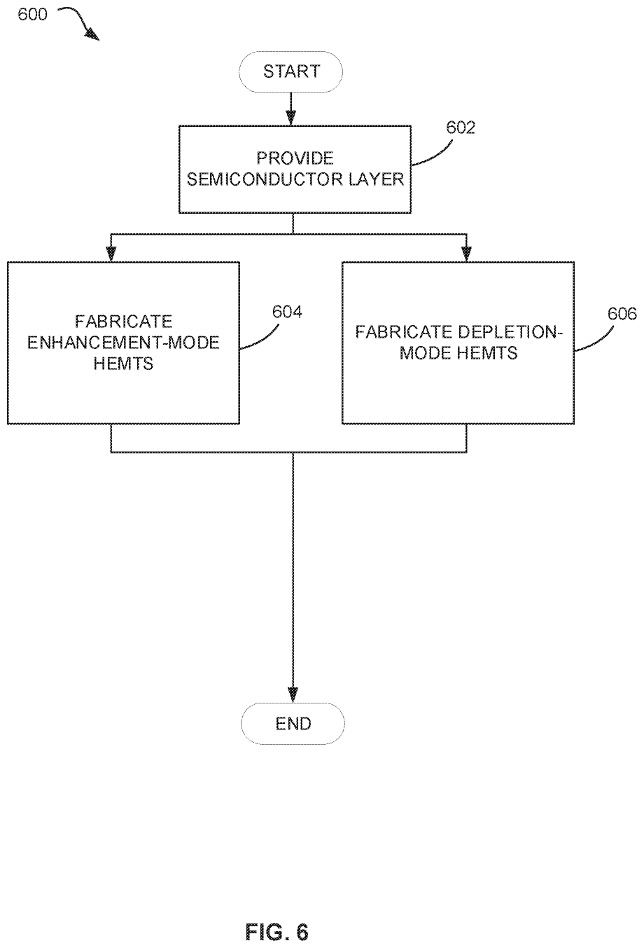

FIG. 6 is a flowchart of an example method 600 to fabricate a wafer containing enhancement-mode HEMTs and depletion-mode HEMTs. In other words, the method 600 describes a method to fabricate enhancement-mode HEMTs and depletion-mode HEMTs in parallel on the same wafer.

At block 602, semiconductor layers capable of sustaining a two-dimensional electron sheet to enable electrical current to flow through the HEMTs is provided. The semiconductor layers may be similar to the semiconductor layers 140 of FIG. 1, and thus for further description of such semiconductor layers, reference to the semiconductor layer 140 of FIG. 1 may be had.

At block 604, an enhancement-mode HEMT is fabricated into the semiconductor layers by the techniques discussed herein. That is, a series of trenches and fins is formed in the semiconductor layer in an active area of the semiconductor layer on which a gate contact terminal of the enhancement-mode HEMT is to be set down, the fins having widths equal to or less than about 30 nm across. The gate contact terminal is set down across the fins. Source contact terminal and drain contact terminals are set down on either side of the gate contact terminal outside of the area.

At block 606, a depletion-mode HEMT is fabricated into the semiconductor layers. Fabrication of the depletion-mode HEMT involves at least setting down a gate contact terminal, and a source contact terminal and a drain contact terminal on either side of the gate contact terminal.

Thus, a wafer containing both depletion-mode HEMTs and enhancement-mode HEMTs may be fabricated. Such parallel processing of depletion-mode HEMTs and enhancement-mode HEMTs may be particularly useful in HEMT-based logic circuits that features integrations of depletion-mode HEMTs and enhancement-mode HEMTs.

Thus, as described herein, a reliable normally-off HEMT may be produced. Such an HEMT may be produced with small fin isolation features and without the need for a separate sacrificial mask, thereby minimizing the risk of damage to the surface of the semiconductor layers. Such reliable normally-off HEMTs may be applicable in radio frequency, power electronics, and digital applications, and may be particularly useful in harsh environments such as automotive and aerospace engine controls, well logging in petroleum exploration, and nuclear reactors.

It should be recognized that features and aspects of the various examples provided above can be combined into further examples that also fall within the scope of the present disclosure. The scope of the claims should not be limited by the above examples but should be given the broadest interpretation consistent with the description as a whole.

1. A method for fabricating an enhancement-mode high-electron-mobility transistor (HEMI), the method comprising:
providing semiconductor layers capable of sustaining a two-dimensional electron sheet to enable electrical current to flow through the HEMT;
forming a series of trenches and fins in the semiconductor layers in an active area of the semiconductor layers on which a gate contact terminal is to be set down, the fins having widths equal to or less than about 30 nm across; and
setting down the gate contact terminal across the fins.

2. The method of claim 1, wherein forming the series of trenches and fins comprises:
covering the semiconductor layers with an electrosensitive resist layer;
patterning the fins into the electrosensitive resist layer by electron beam lithography to form a mask; and
dry etching the trenches into the semiconductor layers through the mask.

3. The method of claim 2, wherein dry etching the series of trenches into the semiconductor layers comprises inductively coupled plasma-reactive ion etching (ICP-RIE).

4. The method of claim 3, wherein the electrosensitive resist layer comprises hydrogen silsesquioxane (HSQ).

5. The method of claim 1, wherein the semiconductor layers comprise a first layer of aluminum gallium nitride (AlGaN) and a second layer of gallium nitride (GaN).

6. The method of claim 1, wherein the gate contact terminal is set down perpendicular to the fins.

7. The method of claim 1, wherein the trenches extend through the semiconductor layers past a depth at which the two-dimensional electron sheet is to be formed.

8. A method of fabricating a wafer containing enhancement-mode high-electron-mobility transistors (HEMTs) and depletion-mode HEMTs, the method comprising:
providing semiconductor layers capable of sustaining a two-dimensional electron sheet to enable electrical current to flow through the HEMTs;
for each enhancement-mode HEMT:
forming a series of trenches and fins in the semiconductor layers over an active area of the semiconductor layers on which a gate contact terminal of the enhancement-mode HEMT is to be set down, the fins having widths equal to or less than about 30 nm across;
setting down the gate contact terminal across the fins; and
setting down a source contact terminal and a drain contact terminal on either side of the gate contact terminal outside of the active area; and
for each depletion-mode HEMI:
setting down a gate contact terminal, and a source contact terminal and a drain contact terminal on either side of the gate contact terminal.

9. A high-electron-mobility transistor (HEMT) comprising:
a drain contact terminal;
a source contact terminal;
semiconductor layers capable of sustaining a two-dimensional electron sheet to enable electrical current to flow through the HEMT, the semiconductor layers comprising an active area on which a gate contact terminal is to be set down, the active area comprising a series of trenches and fins, the fins having widths equal to or less than about 30 nm; and
a gate contact terminal set down across the fins.

10. The HEMT of claim 9, wherein the semiconductor layers comprise a first layer of aluminum gallium nitride (AlGaN) and a second layer of gallium nitride (GaN).

11. The HEMT of claim 9, wherein the gate contact terminal is set down perpendicular to the fins.

12. The HEMT of claim 9, wherein the trenches extend through the semiconductor layers past a depth at which the two-dimensional electron sheet is to be formed.
